(19) United States
(12) Patent Application Publication
(10) Pub. No.: US 2024/0404852 A1
(43) Pub. Date: Dec. 5, 2024

(54) PROCESSING METHOD AND PROCESSING SYSTEM

(71) Applicant: Tokyo Electron Limited, Tokyo (JP)

(72) Inventors: Yohei YAMASHITA, Kikuchi-gun , Kumamoto (JP); Hayato TANOUE, Kikuchi-gun , Kumamoto (JP); Gousuke SHIRAISHI, Kikuchi-gun , Kumamoto (JP)

(21) Appl. No.: 18/697,028

(22) PCT Filed: Sep. 16, 2022
(86) PCT No.: PCT/JP2022/034699

§ 371 Date: Mar. 29, 2024

(30) Foreign Application Priority Data
Sep. 30, 2021 (JP) 2021-161384

(51) Int. Cl. H01L 21/67; B23K 26/36; H01L 21/02; H01L 21/66; H01L 21/68

(52) U.S. Cl. CPC H01L 21/67282; B23K 26/36; H01L 21/02019; H01L 21/02021; H01L 21/02098; H01L 21/67075; H01L 21/681; H01L 22/20

(57) ABSTRACT

A processing method of processing a combined substrate in which a first substrate and a second substrate are bonded to each other includes forming a peripheral modification layer along a boundary between a peripheral portion of the first substrate as a removal target and a central portion of the first substrate; forming a non-bonding region in which bonding strength between the first substrate and the second substrate at the peripheral portion is reduced; forming a reference modification layer, which serves as a determination reference of a formation position of either the peripheral modification layer or the non-bonding region, at a non-bonding surface of the first substrate not bonded to the second substrate; and removing the peripheral portion starting from the peripheral modification layer.

### TECHNICAL FIELD

The various aspects and embodiments described herein pertain generally to a processing method and a processing system.

### BACKGROUND

Patent Document 1 describes a substrate processing system including a modification layer forming apparatus configured to form a modification layer inside a first substrate along a boundary between a central portion and a peripheral portion, which is a removal target, of the first substrate in a combined substrate in which the first substrate and a second substrate are bonded to each other; and a periphery removing apparatus configured to remove the peripheral portion of the first substrate, starting from the modification layer.

### PRIOR ART DOCUMENT

Patent Document 1: International Publication No. 2019/176589

### DISCLOSURE OF THE INVENTION

### Problems to be Solved by the Invention

Exemplary embodiments provide a technique capable of appropriately aligning a laser light radiation device with a laser light radiation target position in a first substrate in a combined substrate in which the first substrate and a second substrate are bonded to each other.

### Means for Solving the Problems

In an exemplary embodiment, a processing method of processing a combined substrate in which a first substrate and a second substrate are bonded to each other includes forming a peripheral modification layer along a boundary between a peripheral portion of the first substrate as a removal target and a central portion of the first substrate; forming a non-bonding region in which bonding strength between the first substrate and the second substrate at the peripheral portion is reduced; forming a reference modification layer, which serves as a determination reference of a formation position of either the peripheral modification layer or the non-bonding region, at a non-bonding surface of the first substrate not bonded to the second substrate; and removing the peripheral portion starting from the peripheral modification layer.

### Effect of the Invention

According to the exemplary embodiment, it is possible to appropriately align the laser light radiation device with the laser light radiation target position in the first substrate in the combined substrate in which the first substrate and the second substrate are bonded to each other.

### BRIEF DESCRIPTION OF THE DRAWINGS

FIG. 1 is a side view illustrating an example structure of a combined wafer to be processed in a wafer processing system.

FIG. 2 is a plan view illustrating a configuration of a wafer processing system according to an exemplary embodiment.

FIG. 3 is a plan view illustrating a configuration of an interface modifying apparatus and an internal modifying apparatus.

FIG. 4 is a longitudinal cross sectional view illustrating the configuration of the interface modifying apparatus and the internal modifying apparatus.

FIG. 5 is a flowchart illustrating main processes of a wafer processing according to the exemplary embodiment.

FIG. 6A to FIG. 6D are explanatory diagrams illustrating the main processes of the wafer processing according to the exemplary embodiment.

FIG. 7 is a transversal cross sectional view illustrating a non-bonding region, a reference modification layer, a peripheral modification layer, and a split modification layer formed in a first wafer.

FIG. 8A to FIG. 8C are explanatory diagrams illustrating the main processes of the wafer processing according to the exemplary embodiment.

FIG. 9A to FIG. 9C are explanatory diagrams illustrating an effect of wet etching on a device layer.

FIG. 10 is an explanatory diagram illustrating another example of removing a peripheral portion of the first wafer.

FIG. 11 is an explanatory diagram illustrating yet another example of removing the peripheral portion of the first wafer.

FIG. 12 is an explanatory diagram illustrating still yet another example of removing the peripheral portion of the first wafer.

FIG. 13A and FIG. 13B are explanatory diagrams illustrating still yet another example of removing the peripheral portion of the first wafer.

### DETAILED DESCRIPTION

In a manufacturing process for a semiconductor device, in a combined substrate in which a first substrate (a silicon substrate such as semiconductor) having devices such as a plurality of electronic circuits formed on a front surface thereof and a second substrate are bonded to each other, removal of a peripheral portion of the first wafer, so-called edge trimming may be performed.

The edge trimming of the first substrate is performed by using a substrate processing system disclosed in, for example, Patent Document 1. That is, a modification layer is formed by radiating laser light (first laser light) to an inside of the first substrate, and the peripheral portion of the first substrate is removed starting from this modification layer. Further, according to the substrate processing system described in Patent Document 1, a modification surface is formed by radiating laser light (second laser light) to an interface at which the first substrate and the second substrate are bonded, so that bonding strength between the first substrate and the second substrate at the peripheral portion as a removal target is reduced, which enables appropriate removal of the peripheral portion.

Since, however, different types of laser light are selected as the first laser light and the second laser light in general, a plurality of laser modules configured to radiate the first laser light and the second laser light independently are disposed in the substrate processing system.

Normally, a radiation position of laser light with respect to a substrate as a laser light radiation target is adjusted by recognizing an end portion (edge portion) of the substrate with a camera and performing an eccentricity control (alignment). However, when using the plurality of laser modules as stated above, there is a risk that the radiation position of the laser light may be misaligned between the laser modules. In this case, there may be a discrepancy between a formation position of a modification layer, which serves as a starting point for separation, and a formation position of a region where bonding strength is reduced. As a result, the peripheral portion of the first substrate may not be properly removed. In this regard, there is a room for improvement in the conventional method of the edge trimming.

In view of the foregoing, exemplary embodiments provide a technique capable of appropriately aligning a laser light radiation device with a laser light radiation target position in the first substrate in the combined substrate in which the first substrate and the second substrate are bonded to each other. Hereinafter, a wafer processing system as a processing system and a wafer processing method as a processing method according to an exemplary embodiment will be described with reference to the accompanying drawings. In the present specification and drawings, parts having substantially the same functions and configurations will be assigned same reference numerals, and redundant description thereof will be omitted.

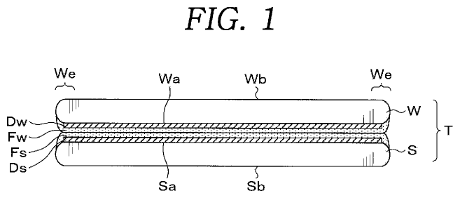

In a wafer processing system 1 to be described later according to the present exemplary embodiment, a processing is performed on a combined wafer T as a combined substrate in which a first wafer W as a first substrate and a second wafer S as a second substrate are bonded to each other as shown in FIG. 1. Hereinafter, in the first wafer W, a surface to be bonded to the second wafer S is referred to as a front surface Wa, and a surface opposite to the front surface Wa is referred to as a rear surface Wb. Likewise, in the second wafer S, a surface to be bonded to the first wafer W is referred to as a front surface Sa, and a surface opposite to the front surface Sa is referred to as a rear surface Sb.

The first wafer W is, for example, a semiconductor wafer such as a silicon substrate, and a device layer Dw including a plurality of devices is formed on the front surface Wa of the first wafer W. Further, a bonding film Fw as a surface film is further formed on the device layer Dw, and the first wafer W is bonded to the second wafer S with the bonding film Fw therebetween. An oxide film (a THOX film, a SiO₂ film, a TEOS film), a SiC film, a SiCN film, or an adhesive is used as an example of the bonding film Fw. Further, a peripheral portion We of the first wafer W is chamfered, and the thickness of this peripheral portion We decreases toward a leading end thereof on a cross section thereof. Furthermore, the peripheral portion We is a portion to be removed in edge trimming to be described later, and is in the range of 0.5 mm to 3 mm from an edge of the first wafer W in a radial direction.

The second wafer S has, for example, the same structure as the first wafer W. A device layer Ds and a bonding film Fs as a surface film are formed on the front surface Sa, and a peripheral portion of the second wafer S is chamfered. However, the second wafer S does not need to be a device wafer on which the device layer Ds is formed, and may be, for example, a support wafer that supports the first wafer W. In this case, the second wafer S functions as a protective member configured to protect the device layer Dw of the first wafer W.

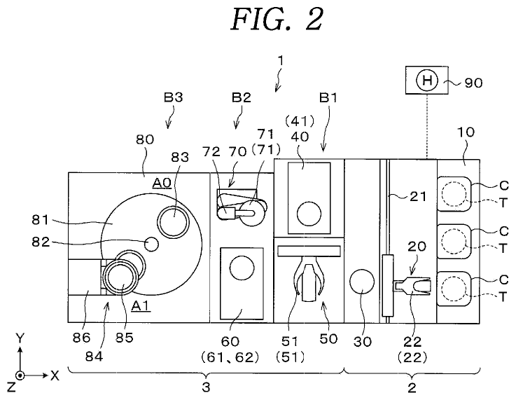

As illustrated in FIG. 2, the wafer processing system 1 has a configuration in which a carry-in/out station 2 and a processing station 3 are connected as one body. In the carry-in/out station 2, a cassette C capable of accommodating therein a plurality of combined wafers T is carried to/from the outside, for example. The processing station 3 is equipped with various types of processing apparatuses configured to perform required processings on the combined wafer T.

The carry-in/out station 2 is equipped with a cassette placing table 10 configured to place a plurality of, e.g., three cassettes C thereon. Further, a wafer transfer device 20 is provided adjacent to the cassette placing table 10 on the negative X-axis side of the cassette placing table 10. The wafer transfer device 20 is configured to be moved on a transfer path 21 extending in the Y-axis direction to transfer the combined wafer T and the like between the cassette C of the cassette placing table 10 and a transition apparatus 30 to be described later.

In the carry-in/out station 2, the transition apparatus 30 configured to deliver the combined wafer T and the like to/from the processing station 3 is provided adjacent to the wafer transfer device 20 on the negative X-axis side of the wafer transfer device 20.

The processing station 3 is provided with, for example, three processing blocks B1 to B3. The first processing block B1, the second processing block B2, and the third processing block B3 are arranged in this order from the positive X-axis side (carry-in/out station 2 side) toward the negative X-axis side.

The first processing block B1 includes an etching apparatus 40 configured to etch a ground surface of the first wafer W ground in a processing apparatus 80 to be described later, a cleaning apparatus 41 configured to clean the first wafer W after being etched by the etching apparatus 40, and a wafer transfer device 50. The etching apparatus 40 and the cleaning apparatus 41 are stacked on top of each other. Here, the number and the layout of the etching apparatus 40 and the cleaning apparatus 41 are not limited to the shown example.

The cleaning apparatus 41 is configured to radiate laser light for cleaning (for example, a UV femtosecond laser) to the first wafer W after being etched by the etching apparatus 40 to remove any residue (deposit or the like) remaining on the first wafer W. Further, the cleaning apparatus 41 also radiates the laser light for cleaning to the bonding films Fw and Fs remaining on the front surface Sa of the second wafer S (hereinafter, referred to as “residual film”) after the peripheral portion We is removed as will be described later, thus removing the residual films by laser ablation. In other words, by removing the bonding films Fw and Fs left after the removal of the peripheral portion We, the front surface Sa of the second wafer S is exposed, and the peripheral portion We of the first wafer W is removed completely.

The wafer transfer device 50 is disposed on the negative X-axis side of the transition apparatus 30. The wafer transfer device 50 has, for example, two transfer arms 51 configured to hold and transfer the combined wafer T. Each transfer arm 51 is configured to be movable in a horizontal direction and a vertical direction and pivotable around a horizontal axis and a vertical axis. The wafer transfer device 50 is configured to transfer the combined wafer T and the like to/from the transition apparatus 30, the etching apparatus 40, the cleaning apparatus 41, an interface modifying apparatus 60 to be described later, an internal modifying apparatus 61 to be described later, and a separating apparatus 62 to be described later, that is, to/from the apparatuses within the wafer processing system 1 other than the processing apparatus 80 to be described later.

The second processing block B2 includes the interface modifying apparatus 60 configured to form a non-bonding region Ae and a reference modification layer M1 to be described later; the internal modifying apparatus 61 configured to form a peripheral modification layer M2 and a split modification layer M3 serving as starting points for separation of the first wafer W; the separating apparatus 62 configured to remove the peripheral portion We of the first wafer W; and a wafer transfer device 70. The interface modifying apparatus 60, the internal modifying apparatus 61, and the separating apparatus 62 are stacked on top of each other. Furthermore, the number and the layout of the interface modifying apparatus 60, the internal modifying apparatus 61, and the separating apparatus 62 are not limited to the shown example. For instance, instead of stacking the interface modifying apparatus 60, the internal modifying apparatus 61, and the separating apparatus 62, at least one of them may be disposed adjacent to another in a horizontal direction.

The interface modifying apparatus 60 is configured to radiate laser light L1 for interface (for example, a CO₂ laser) to, for example, the device layer Dw and the bonding film Fw formed on the first wafer W to form the non-bonding region Ae in which bonding strength between the first wafer W and the second wafer S is reduced. Further, the interface modifying apparatus 60 also radiates the laser light L1 for interface to, for example, the rear surface Wb of the first wafer W to form a reference modification layer M1 that serves as a reference mark for alignment when forming the peripheral modification layer M2 in the internal modifying apparatus 61.

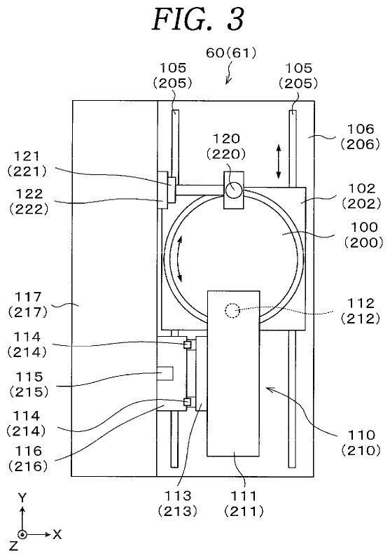

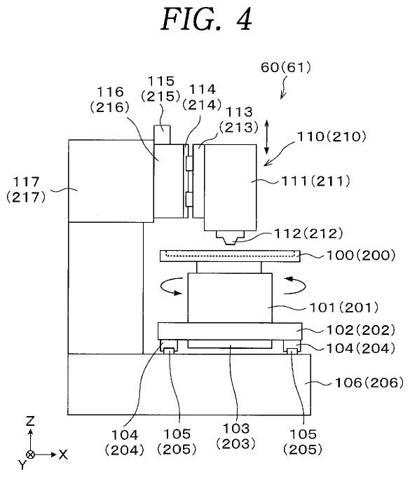

As depicted in FIG. 3 and FIG. 4, the interface modifying apparatus 60 has a chuck 100 configured to hold the combined wafer T on a top surface thereof. The chuck 100 serves to attract and hold a non-bonding surface (rear surface Sb) of the second wafer S not bonded to the first wafer W.

The chuck 100 is supported by a slider table 102 with an air bearing 101 therebetween. A rotating mechanism 103 is provided on a bottom surface of the slider table 102. The rotating mechanism 103 has, for example, a motor as a driving source embedded therein. The chuck 100 is configured to be rotatable around a θ axis (vertical axis) by the rotating mechanism 103 with the air bearing 101 therebetween. The slider table 102 is configured to be movable along a rail 105 extending in the Y-axis direction by a horizontally moving mechanism 104 provided on a bottom surface thereof. The rail 105 is provided on a base 106. In addition, although not particularly limited, a driving source of the horizontally moving mechanism 104 may be a linear motor, for example.

A laser radiation system 110 is provided above the chuck 100. The laser radiation system 110 has a laser head 111 and a lens 112. The lens 112 may be configured to be movable up and down by an elevating mechanism (not shown).

The laser head 111 has a non-illustrated laser oscillator configured to oscillate laser light in a pulse shape. That is, the laser light radiated from the laser radiation system 110 to the combined wafer T held by the chuck 100 is a so-called pulse laser, and its power is repeated between 0 (zero) and a maximum value. Further, the laser head 111 may have other devices of the laser oscillator, such as an amplifier.

The lens 112 is a cylindrical member, and radiates the laser light L1 for interface to the combined wafer T held by the chuck 100.

The laser head 111 is supported on a supporting member 113. The laser head 111 is configured to be movable up and down by an elevating mechanism 115 along a rail 114 extending in a vertical direction. Also, the laser head 111 is configured to be movable in the Y-axis direction by a moving mechanism 116. In addition, each of the elevating mechanism 115 and the moving mechanism 116 is supported by a supporting column 117.

A first imaging device 120 is disposed above the chuck 100 on the positive Y-axis side of the laser radiation system 110. The first imaging device 120 includes, as an example, a macro camera with an imaging magnification of 2 times, and has a numerical aperture capable of detecting at least an outer end of the first wafer W, as will be described later. The first imaging device 120 is configured to be movable up and down by an elevating mechanism 121, and is also configured to be movable in the Y-axis direction by a moving mechanism 122. The moving mechanism 122 is supported by the supporting column 117.

The first imaging device 120 is configured to image the outer end of the first wafer W (combined wafer T). The image obtained by the first imaging device 120 is used for, for example, alignment of the first wafer W, which will be described later, and determination of a radiation position of laser light for interface (alignment of the laser radiation system 110), which will be described later. The first imaging device 120 includes, for example, a coaxial lens, and is configured to radiate infrared light (IR) and receive reflected light from an object.

As shown in FIG. 1, when the peripheral portion We of the first wafer W is chamfered (rounded), it is difficult to accurately detect the outer end of the first wafer W by using a camera with a high numerical aperture. In the present exemplary embodiment, however, by using a macro camera with a low numerical aperture as the first imaging device 120 configured to image the outer end of the first wafer W (combined wafer T), the outer end can be detected even when the peripheral portion We of the first wafer W is chamfered (rounded).

However, if the first imaging device 120 is capable of properly focusing on the outer end of the first wafer W even with a micro camera having a higher numerical aperture than the macro camera due to such a factor as the shape of the first wafer W or the like, the first imaging device 120 may be equipped with a micro camera (not shown) instead of or in addition to the macro camera. The imaging magnification of the micro camera is 10 times, the field of view thereof is approximately ⅕ of that of the first imaging device 120, and the pixel size thereof is approximately ⅕ of that of the first imaging device 120. When detecting the outer end of the first wafer W by using the micro camera, the alignment of the first wafer W and the determination of the radiation position of the laser light for interface can be carried out with higher precision.

Further, in the shown example, the chuck 100 is configured to be rotated and horizontally moved relative to the laser head 111 by the rotating mechanism 103 and the horizontally moving mechanism 104. However, the laser head 111 may be configured to be rotated and horizontally moved relative to the chuck 100. Still alternatively, both the chuck 100 and the laser head 111 may be configured to be rotatable and horizontally movable relative to each other.

The internal modifying apparatus 61 is configured to radiate laser light L2 for inside (for example, NIR light such as a YAG laser) to an inside of the first wafer W. In the internal modifying apparatus 61, by modifying the first wafer W at a converging point of the laser light L2 for inside, the peripheral modification layer M2 as a starting point for removing the peripheral portion We of the first wafer W and the split modification layer M3 as a starting point for breaking the peripheral portion We to be removed into smaller pieces are formed.

The internal modifying apparatus 61 has approximately the same configuration as the interface modifying apparatus 60. That is, the internal modifying apparatus 61 has a chuck 200 configured to hold the combined wafer T, a laser radiation system 210, and a second imaging device 220.

The chuck 200 has an air bearing 201, a slider table 202, a rotating mechanism 203, a horizontally moving mechanism 204, a rail 205, and a base 206, and is configured to be rotatable around a θ axis (vertical axis) and movable in a horizontal direction.

The laser radiation system 210 has a laser head 211, a lens 212, a supporting member 213, a rail 214, an elevating mechanism 215, and a moving mechanism 216. Each of the elevating mechanism 215 and the moving mechanism 216 is supported by a supporting column 217. The laser radiation system 210 radiates the laser light L2 for inside to the combined wafer T held by the chuck 200. The second imaging device 220 is configured to be movable by the elevating mechanism 221 and the moving mechanism 222. The moving mechanism 222 is supported by the supporting column 217.

Further, the second imaging device 220 includes, as an example, a micro camera with an imaging magnification of 10 times. The second imaging device 220 images the reference modification layer M1 formed at the rear surface Wb of the first wafer W (combined wafer T). The image obtained by the second imaging device 220 is used for, as an example, determination of a radiation position of the laser light L2 for inside (alignment of the laser radiation system 210), which will be described later. The second imaging device 220 includes, by way of example, a coaxial lens, and is configured to radiate infrared light (IR) and receive reflected light from an object.

In the present exemplary embodiment, in order to image the reference modification layer M1 formed at the rear surface Wb (flat surface) of the first wafer W instead of the round outer end, a micro camera with a high numerical aperture may be used as the second imaging device 220. In this way, by using the micro camera as the second imaging device 220, it is possible to determine the radiation position of the laser light L2 for inside with higher precision as compared to a case of imaging the reference modification layer M1 with a macro camera having a low numerical aperture.

Here, however, the second imaging device 220 is not limited to the micro camera, and it may be equipped with a macro camera (not shown) instead of or in addition to the micro camera.

The separating apparatus 62 is configured to remove at least the peripheral portion We of the first wafer W from the second wafer S, that is, performs the edge trimming, starting from the peripheral modification layer M2 formed in the internal modifying apparatus 61. A method of the edge trimming is not particularly limited. As an example, in the separating apparatus 62, a blade having a wedge shape may be inserted. As another example, an impact may be applied to the peripheral portion We by ejecting an air blow or a water jet toward the peripheral portion We.

The wafer transfer device 70 is disposed on the positive Y-axis side of the interface modifying apparatus 60 and the internal modifying apparatus 61, for example. The wafer transfer device 70 has, for example, two transfer arms 71 configured to attract and hold the combined wafer T on an attracting/holding surface (not shown) thereof to transfer the combined wafer T. Each transfer arm 71 is supported by a multi-joint arm member 72, and is configured to be movable in a horizontal direction and a vertical direction and pivotable around a horizontal axis and a vertical axis. The wafer transfer device 70 is configured to transfer the combined wafer T and the like to/from the etching apparatus 40, the cleaning apparatus 41, the interface modifying apparatus 60, the internal modifying apparatus 61, the separating apparatus 62, and the processing apparatus 80 to be described later.

The third processing block B3 is equipped with the processing apparatus 80.

The processing apparatus 80 has a rotary table 81. The rotary table 81 is configured to be rotatable about a vertical rotation center line 82 by a rotating mechanism (not shown). On the rotary table 81, two chucks 83 are provided to attract and hold the combined wafer T. The chucks 83 are evenly arranged on the same circumference as the rotary table 81. The two chucks 83 are configured to be moved to a delivery position A0 and a processing position A1 as the rotary table 81 is rotated. Further, each of the two chucks 83 is configured to be rotatable around a vertical axis by a rotating mechanism (not shown).

A delivery of the combined wafer T is performed at the delivery position A0. A grinding device 84 is disposed at the processing position A1 to grind the first wafer W while attracting and holding the second wafer S with the chuck 83. The grinding device 84 has a grinder 85 equipped with a grinding whetstone (not shown) configured to be rotatable in an annular shape. Further, the grinder 85 is configured to be movable in a vertical direction along a supporting column 86.

The wafer processing system 1 described above is provided with a control device 90. The control device 90 is, for example, a computer equipped with a CPU, a memory, and the like, and has a program storage (not shown). The program storage stores therein a program for controlling the processing of the combined wafer T in the wafer processing system 1. The program may have been recorded on a computer-readable recording medium H, and may be installed from the recording medium H into the control device 90.

Now, a wafer processing performed by using the wafer processing system 1 configured as described above will be explained. In the present exemplary embodiment, the combined wafer T is previously formed in a bonding apparatus (not shown) outside the wafer processing system 1.

First, the cassette C accommodating therein a plurality of combined wafers T is placed on the cassette placing table 10 of the carry-in/out station 2. Then, the combined wafer T in the cassette C is taken out by the wafer transfer device 20 and transferred to the transition apparatus 30. The combined wafer T transferred to the transition apparatus 30 is then transferred to the interface modifying apparatus 60 by the wafer transfer device 50.

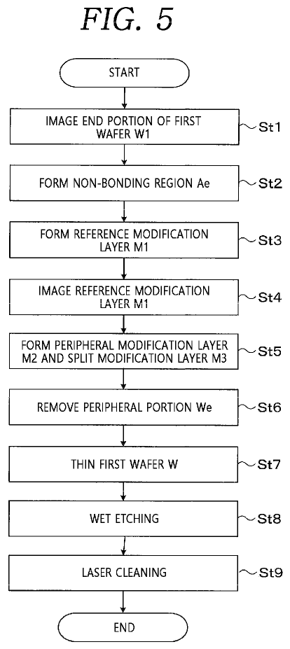

In the interface modifying apparatus 60, the combined wafer T held by the chuck 100 is first moved to a first imaging position. The first imaging position is a position where the first imaging device 120 can image the outer end (edge portion) of the first wafer W. At the first imaging position, while rotating the chuck 100, an image of the outer end of the first wafer W is taken by the first imaging device 120 in 360 degrees in a circumferential direction of the first wafer W (process St1 in FIG. 5). The obtained image is outputted from the first imaging device 120 to the control device 90.

The control device 90 calculates an eccentric amount between a center of the chuck 100 and a center of the first wafer W from the image sent from the first imaging device 120. Also, based on the calculated eccentric amount, the control device 90 calculates a moving amount of the chuck 100 to correct a Y-axis component of the eccentric amount. The control device 90 moves the chuck 100 horizontally along the Y-axis direction based on the calculated moving amount, thus correcting the eccentricity between the center of the chuck 100 and the center of the first wafer W.

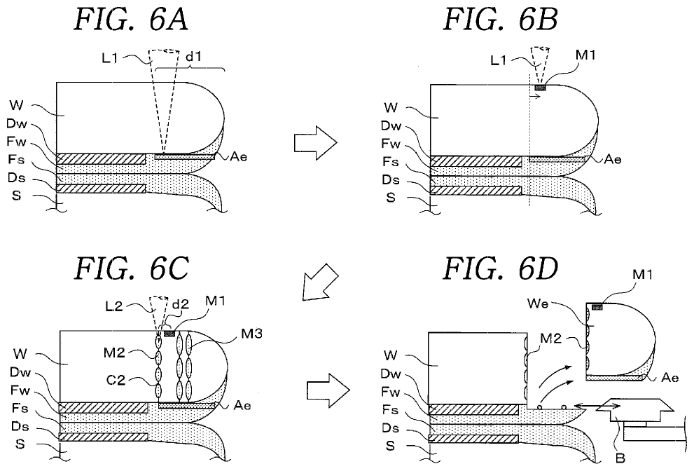

Further, the control device 90 specifies the position of the outer end of the first wafer W from the image of the first imaging device 120. Also, based on the specified position of the outer end of the first wafer W, the control device 90 sets a radiation area of the laser light L1 for interface for forming the non-bonding region Ae. For example, the radiation area of the laser light L1 for interface is set as an annular area having a required width d1 (see FIG. 6A) from the outer end of the first wafer W in a radial direction.

Once the eccentricity between the chuck 100 and the first wafer W is corrected and the radiation area of the laser light L1 for interface is set, the laser light L1 for interface is radiated in a pulse shape to a bonding interface between the first wafer W and the second wafer S in the radiation area set in the process St1, while rotating the chuck 100 and the laser head 111 relatively and moving them relatively in a horizontal direction along the Y-axis direction (process St2 in FIG. 5). As a result, the bonding interface between the first wafer W and the second wafer S (in the shown example, the interface between the first wafer W and the bonding film Fw) is modified. In addition, the modification of the bonding interface in the exemplary embodiment is assumed to include, by way of example, amorphization of the bonding film Fw at the radiation position of the laser light L1 for interface, separation of the first wafer W and the second wafer S, and so forth.

In the interface modifying apparatus 60, by modifying the radiation position of the laser light L1 for interface at the interface between the first wafer W and the second wafer S, there is formed the non-bonding region Ae in which the bonding strength of the first wafer W and the second wafer S is reduced, as shown in FIG. 6A and FIG. 7. In the edge trimming to be described later, the peripheral portion We of the first wafer W, which is a target portion to be removed, is removed. Since the non-bonding region Ae with the bonding strength reduced in this way is provided, the removal of the peripheral portion We may be carried out appropriately.

Once the non-bonding region Ae is formed, the position of the converging point of the laser light L1 for the interface (radiation position of the laser light L1 for the interface) is moved to the rear surface Wb of the first wafer W in the same interface modifying apparatus 60. Then, while rotating the chuck 100 and the laser head 111 relatively, the laser light L1 for interface is radiated in a pulse shape to the rear surface Wb of the first wafer W (process St3 in FIG. 5). As a result, the rear surface Wb of the first wafer W is modified, as shown in FIG. 6B and FIG. 7.

In the interface modifying apparatus 60, by radiating the laser light L1 for interface to the rear surface Wb of the first wafer W as described above to thereby modify the rear surface Wb, the reference modification layer M1 is formed to serve as a reference for alignment of the laser radiation system 210 when forming the peripheral modification layer M2.

Furthermore, in order to appropriately radiate the laser light L2 for inside to be described later to a target position within the first wafer W, it is desirable to set the formation position of the reference modification layer M1 in the radial direction of the first wafer W to be a position slightly shifted from a radially inner end portion (hereinafter simply referred to as “inner end”) of the non-bonding region Ae, desirably, a position radially outer than the inner end of the non-bonding region Ae, as illustrated in FIG. 6B. However, the formation position of the reference modification layer M1 may be radially inside the inner end of the non-bonding region Ae in the rear surface Wb of the first wafer W.

The combined wafer T having the non-bonding region Ae and the reference modification layer M1 formed therein is then transferred to the internal modifying apparatus 61 by the wafer transfer device 70. In the internal modifying apparatus 61, the combined wafer T held by the chuck 200 is first moved to a second imaging position. The second imaging position is a position where the second imaging device 220 can image the reference modification layer M1 formed in the first wafer W. At the second imaging position, while rotating the chuck 200, an image of the reference modification layer M1 is taken by the second imaging device 220 in 360 degrees in the circumferential direction of the first wafer W (process St4 in FIG. 5). The obtained image is outputted from the second imaging device 220 to the control device 90.

The control device 90 calculates an eccentric amount between the center of the chuck 200 and the center of the first wafer W from the image of the second imaging device 220. Also, based on the calculated eccentric amount, the control device 90 calculates a moving amount of the chuck 200 to correct a Y-axis component of the eccentric amount. The control device 90 moves the chuck 200 horizontally along the Y-axis direction based on this calculated moving amount to correct the eccentricity between the center of the chuck 200 and the center of the first wafer W.

Additionally, the control device 90 specifies the formation position of the reference modification layer M1 from the image of the second imaging device 220. Also, based on the specified formation position of the reference modification layer M1, the control device 90 sets a radiation position (position in the radial direction) of the laser light L2 for inside for forming the peripheral modification layer M2. For example, the radiation position of the laser light L2 for inside is set to be a position moved from the formation position of the reference modification layer M1 by a required distance d2 (see FIG. 6C) in the radial direction, specifically, a position corresponding to the inner end of the non-bonding region Ae.

Once the eccentricity between the chuck 200 and the first wafer W is corrected and the radiation position of the laser light L2 for inside is set, the laser light L2 for inside is radiated to the inside of the first wafer W to form the peripheral modification layer M2 and the split modification layer M3 in sequence, as illustrated in FIG. 6C and FIG. 7 (process St5 in FIG. 5). The peripheral modification layer M2 serves as a starting point for removing the peripheral portion We in the edge trimming to be described later. The split modification layer M3 serves as a starting point for breaking the peripheral portion We to be removed into smaller pieces. In addition, in the drawings to be referred to in the following description, illustration of the split modification layer M3 may be omitted in order to avoid complication of the illustration. Further, the order in which the peripheral modification layer M2 and the split modification layer M3 are formed is not particularly limited.

Conventionally, in the internal modifying apparatus 61, the radiation position of the laser light L2 for inside (formation position of the peripheral modification layer M2) is determined based on the outer end of the first wafer W, the same as in the process St1. In this case, since the peripheral portion We of the first wafer W is chamfered as shown in FIG. 1, an optical system (for example, a macro camera) having a low numerical aperture NA as stated above needs to be used as the imaging device, and detection accuracy for the outer end of the first wafer W may not be high. Further, if the radiation positions of both the laser light L1 for interface and the laser light L2 for inside are determined based on the outer end of the first wafer W, such a deviation in the detection accuracy may accumulate between in the interface modifying apparatus 60 and in the internal modifying apparatus 61, and, as a result, there has been a risk that the formation position of the peripheral modification layer M2 may be significantly deviated from the target position. To elaborate, if there is a deviation of about ±10 μm in the detection accuracy in each of the apparatuses 60 and 61, there is a risk that these deviations may accumulate, resulting in the deviation of up to approximately 20 μm. For this reason, there has been a risk that the peripheral portion We may not be properly removed.

In view of the foregoing, according to the technique of the present disclosure, the radiation position of the laser light L2 for inside is determined (the laser radiation system 210 is aligned) with the reference modification layer M1 formed in the rear surface Wb (flat surface) of the first wafer W, instead of the outer end of the first wafer W, as a reference. As a result, as compared to the case where the outer end of the chamfered first wafer W is used as the reference, it becomes possible to use an optical system (micro camera) with a higher numerical aperture NA, so that more precise alignment of the laser radiation system 210 can be carried out. More specifically, the formation position of the peripheral modification layer M2 and the formation area of the non-bonding region Ae can be more appropriately controlled, and, as a consequence, the peripheral portion We of the first wafer W can be appropriately removed.

In addition, in the present exemplary embodiment, the micro camera is used as the second imaging device 220 as stated above. However, even when a macro camera is used as the second imaging device 220, the formation position of the peripheral modification layer M2 with respect to the formation area of the non-bonding region Ae can be appropriately determined as compared to the case where the formation position of the peripheral modification layer M2 is determined based on the outer end of the first wafer W.

Here, however, by using the micro camera having the higher numerical aperture than the macro camera as the second imaging device 220, the detection accuracy for the reference modification layer M1 is improved, and, as a result, the formation position of the peripheral modification layer M2 with respect to the formation area of the non-bonding region Ae can be determined more appropriately.

In addition, inside the first wafer W, a crack C2 develops in a thickness direction from the peripheral modification layer M2. The development of the crack C2 is controlled by adjusting, for example, the formation position of the peripheral modification layer M2 in the thickness direction of the first wafer W, or by adjusting, for example, an output and a blurring level of the laser light in the formation of the peripheral modification layer M2. In the edge trimming to be described later, the peripheral portion We is removed from the second wafer S starting from the crack C2 in addition to the peripheral modification layer M2.

The combined wafer T in which the peripheral modification layer M2 and the split modification layer M3 are formed is then transferred to the separating apparatus 62 by the wafer transfer device 50. In the separating apparatus 62, the peripheral portion We of the first wafer W is removed, that is, the edge trimming is performed, as shown in FIG. 6D (process St6 in FIG. 5). At this time, the peripheral portion We is separated from the central portion (radially inside the peripheral portion We) of the first wafer W starting from the peripheral modification layer M2, and is completely separated from the second wafer S starting from the non-bonding region Ae. At this time, the peripheral portion We to be removed is broken into smaller pieces, starting from the split modification layer M3.

In removing the peripheral portion We, a blade B, which is formed to have a wedge shape, for example, may be inserted into the interface between the first wafer W and the second wafer S forming the combined wafer T (see FIG. 6D).

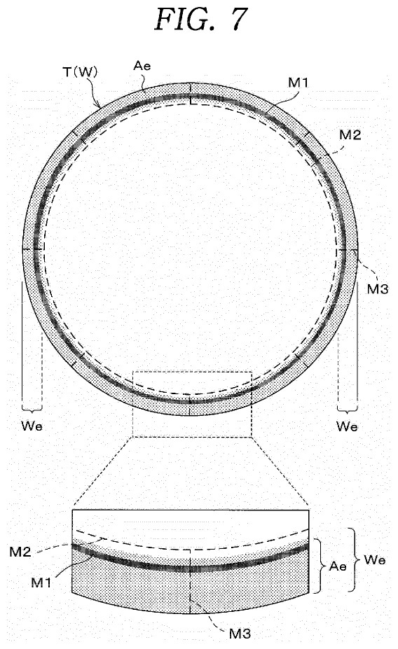

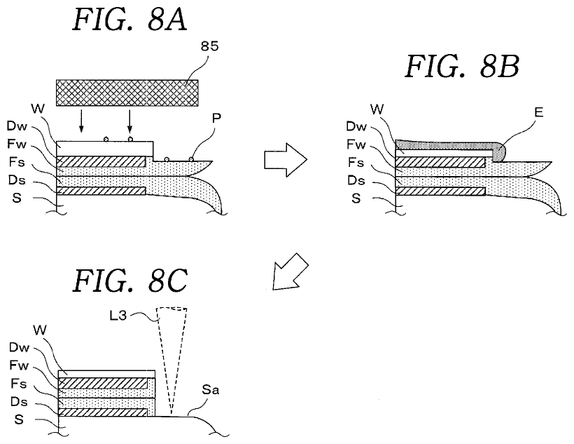

The combined wafer T from which the peripheral portion We of the first wafer W has been removed is then transferred to the chuck 83 of the processing apparatus 80 by the wafer transfer device 70. Next, the chuck 83 is moved to the processing position A1, and the rear surface Wb of the first wafer W is ground by the grinding device 84, as shown in FIG. 8A (process St7 in FIG. 5). By this grinding process, the first wafer W (combined wafer T) is reduced to a required target thickness. Thereafter, the ground surface of the first wafer W may be cleaned with a cleaning liquid by using a cleaning liquid nozzle (not shown).

Next, the combined wafer T is transferred to the etching apparatus 40 by the wafer transfer device 70. In the etching apparatus 40, the ground surface of the first wafer W is wet-etched by a chemical liquid E, as shown in FIG. 8B (process St8 in FIG. 5). A grinding mark may exist on the ground surface processed by the above-described processing apparatus 80. In this process St8, by performing the wet etching, the first wafer W (combined wafer T) is further thinned, and the ground surface is smoothed as a result of removing the grinding mark.

Subsequently, the combined wafer T is transferred to the cleaning apparatus 41 by the wafer transfer device 50. In the cleaning apparatus 41, by radiating laser light L3 for cleaning to the residual film (the bonding films Fw and Fs) on the front surface Sa of the second wafer S that is exposed as a result of the removal of the peripheral portion We, the residual film and particles P are removed to expose the front surface Sa of the second wafer S, as illustrated in FIG. 8C (process St9 in FIG. 5).

In this process St9, in order to completely remove the peripheral portion We of the first wafer W as described above, the entire front surface Sa of the second wafer S corresponding to the peripheral portion We is radiated with the laser light L3 for cleaning.

Specifically, while rotating the combined wafer T and moving the radiation position of the laser light L3 for cleaning in the radial direction through Galvano scanning, the laser light L3 for cleaning is periodically radiated from a laser head. As a result, the laser light L3 for cleaning can be radiated to the entire surface of the residual film, that is, the residual film on the front surface Sa can be completely removed.

Furthermore, in the cleaning apparatus 41, the ground surface of the first wafer W and the rear surface Sb of the second wafer S may be further cleaned with a cleaning liquid by using a cleaning liquid nozzle (not shown).

To this end, in the present exemplary embodiment, after wet-etching the ground surface of the first wafer W (process St8) as stated above, the residual film on the front surface Sa of the second wafer S is removed (process St9). The order in which the wet etching and the removal of the residual film are performed is not particularly limited. To be specific, the residual film may be removed after the removal of the peripheral portion We of the first wafer W (process St6) and before the grinding process (process St7), or may be removed after the grinding process (process St7) and before the wet etching (process St8).

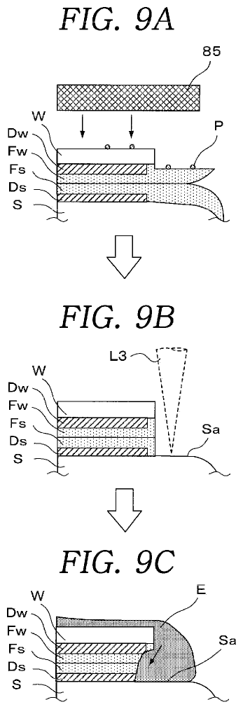

However, when removing the residual film prior to the wet etching (process St8), there is a risk that the device layers Dw and Ds may be affected by the chemical liquid supplied in the wet etching. Specifically, when the wet etching is performed after the grinding process (process St7) shown in FIG. 9A and the removal of the residual film by the laser light L3 for cleaning shown in FIG. 9B, side surfaces of the bonding films Fw and Fs exposed as a result of the removal of the residual film may be removed due to the chemical liquid E, causing damage to the device layers Dw and Ds, as shown in FIG. 9C.

In consideration of this risk, it is desirable that the wet etching of the ground surface of the first wafer W (process St8) and the removal of the residual film on the front surface Sa of the second wafer S (process St9) are performed in this order.

Afterwards, the combined wafer T after being subjected to all the required processes is transferred to the transition apparatus 30 by the wafer transfer device 50, and is then transferred to the cassette C on the cassette placing table 10 by the wafer transfer device 20. In this way, the series of processes of the wafer processing in the wafer processing system 1 are completed.

According to the above-described exemplary embodiment, before the peripheral modification layer M2, which serves as the starting point for removing the peripheral portion We, is formed within the first wafer W, the reference modification layer M1 that serves as the reference for the radiation position of the laser light L2 for inside is formed in the rear surface Wb of the first wafer W. In the formation of the peripheral modification layer M2 within the first wafer W, the radiation position of the laser light L2 for inside is determined based on the reference modification layer M1 formed in the rear surface Wb of the first wafer W as the target.

Accordingly, since the target formed at the rear surface Wb of the first wafer W, that is, at the flat surface is detected with the camera, it is possible to use the optical system (micro camera) having the higher numerical aperture NA, as compared to the a conventional case where the chamfered outer end (edge portion) is detected with the camera, and as a result, more precise adjustment of the radiation position of the laser light L2 for inside (alignment of the laser radiation system 210) can be carried out.

Thus, even in the case where the plurality of laser radiation devices (in the present exemplary embodiment, the interface modifying apparatus 60 and the internal modifying apparatus 61) are provided in the wafer processing system 1, it is possible to suppress the occurrence of the discrepancy in the radiation position of laser light between these laser radiation devices.

Furthermore, according to the above-described exemplary embodiment, the reference modification layer M1 as the target is formed at the position slightly shifted radially outwards from the incident position of the laser light L2 for inside (formation position of the peripheral modification layer M2) in the rear surface Wb of the first wafer W.

Normally, when the silicon of the first wafer W is modified by laser ablation, the laser light L2 for inside is not properly transmitted through the modified portion (the reference modification layer M1 in the present exemplary embodiment). Therefore, there is a risk that the peripheral modification layer M2 may not be properly formed.

In view of this, according to the above-described exemplary embodiment, since the reference modification layer M1 is formed at the position slightly shifted from the incident position of the laser light L2 for inside, incidence of the laser light L2 for inside is not inhibited in the formation of the peripheral modification layer M2, so that the peripheral modification layer M2 can be appropriately formed.

In addition, when the reference modification layer M1 is formed at the rear surface Wb of the first wafer W as described above, the laser light L2 for inside may not properly reach the inside of the first wafer W. In this case, if the reference modification layer M1 is formed radially outside the incident position of the laser light L2 for inside, there is a risk that the split modification layer M3 shown in FIG. 6C may not be formed properly.

Taking this into account, it is desirable that the formation position of the reference modification layer M1 is set to be a position that is slightly outside the incident position of the laser light L2 for inside in the radial direction and does not overlap with the formation position of the split modification layer M3 when viewed from the top, or a position slightly inside the incident position of the laser light L2 for inside in the radial direction.

In addition, in the above-described exemplary embodiment, the crack C2 that develops in the thickness direction during the formation of the peripheral modification layer M2 is made to reach the front surface Wa and the rear surface Wb of the first wafer W approximately perpendicularly thereto. However, the way the crack C2 develops is not limited to thereto.

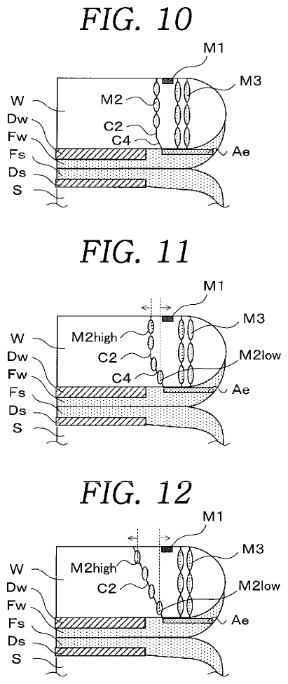

Specifically, as illustrated in FIG. 10, for example, the formation position of the peripheral modification layer M2 may be controlled to be slightly inside an inner end of the non-bonding region Ae in the radial direction, thus allowing the crack C2 developing downwards from the peripheral modification layer M2 formed at a lower side to be connected to a crack C4 developing obliquely upwards from the inner end of the non-bonding region Ae.

In this case, as compared to the case where the crack C2 reaches the front surface Wa approximately perpendicularly thereto, the crack can be allowed to stably reach the rear surface Wb of the first wafer W from the front surface Wa, so that the proper removal of the peripheral portion We can be carried out stably.

Moreover, even in this case, by forming the reference modification layer M1 at a position slightly shifted from the formation position of the peripheral modification layer M2 in the rear surface Wb as shown in FIG. 10, the radiation position of the laser light L2 for inside can be appropriately determined, the same as in the above-described exemplary embodiment. Furthermore, in this case, as shown in FIG. 10, the formation position of the reference modification layer M1 does not necessarily need to be shifted from a position corresponding to the inner end of the non-bonding region Ae.

In addition, instead of developing only the crack C4 diagonally upwards from the inner end of the non-bonding region Ae as shown in FIG. 10, adjacent peripheral modification layers M2 may be formed to be shifted from each other in the thickness direction and the radial direction, that is, to be arranged obliquely on the front surface Wa side within the first wafer W, as illustrated in FIG. 11. In this case, as compared to the case shown in FIG. 10, the crack C4 can be made to propagate diagonally upwards more easily.

Also, in this case, it is desirable that the formation position of the reference modification layer M1 is set to be slightly radially outside a peripheral modification layer M2_{low} formed at the radially outermost side among a plurality of peripheral modification layers M2, or slightly radially inside a peripheral modification layer M2_{high} formed at the radially innermost side, as illustrated in FIG. 11.

As another example, instead of arranging the adjacent peripheral modification layers M2 obliquely only on the front surface Wa side within the first wafer W as shown in FIG. 11, the peripheral modification layers M2 may be arranged obliquely throughout the entire thickness of the first wafer W, as depicted in FIG. 12. In this case, formation of a crack in the peripheral portion We to be removed and in the central portion of the first wafer W after the removal of the peripheral portion We may be suppressed. Accordingly, generation of particles inside the wafer processing system 1 may be suppressed, and deterioration of the quality of the first wafer W (device wafer) as a product may be suppressed.

Furthermore, in this case, it is desirable that the formation position of the reference modification layer M1 is set to be slightly radially outside the peripheral modification layer M2_{low} formed at the radially outermost side among the plurality of peripheral modification layers M2, or slightly radially inside a peripheral modification layer M2_{high} formed at the radially innermost side, as illustrated in FIG. 12.

In addition, in the above-described exemplary embodiment, the first wafer W being subjected to the edge trimming is thinned by the grinding process in the processing apparatus 80. However, the way to thin the first wafer W is not limited to thereto.

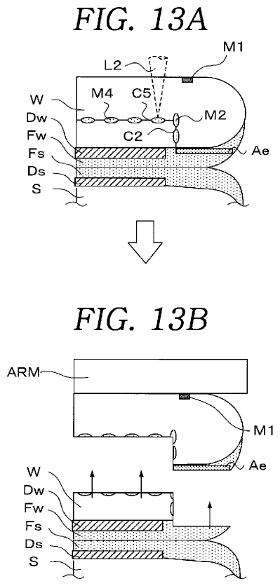

To elaborate, in the combined wafer T in which the non-bonding region Ae and the reference modification layer M1 are formed, not only the peripheral modification layer M2, which serves as the starting point for the separation of the peripheral portion We, but also an internal modification layer M4, which serves as a starting point for thinning due to the separation of the first wafer W, is formed in the internal modifying apparatus 61, as shown in FIG. 13A. A crack C5 extending in a plane direction of the first wafer W is formed from the internal modification layer M4, and this crack C5 is connected to the peripheral modification layer M2 or an upper end of the crack C2 extending from the peripheral modification layer M2 in the thickness direction.

Further, in the separating apparatus 62, the first wafer W is attracted and held by an attracting/holding surface belonging to a separation arm ARM, and the second wafer S is attracted and held by a non-illustrated chuck, as illustrated in FIG. 13B. Afterwards, by raising the separation arm ARM in the state that the first wafer W is attracted to and held on the attracting/holding surface thereof, the first wafer W is separated starting from the internal modification layer M4 to be thinned. At this time, the peripheral portion We of the first wafer W is separated from the second wafer S as one body with the rear surface Wb side of the first wafer W.

Even in this case, by forming the reference modification layer M1 at the position slightly shifted from the formation position of the peripheral modification layer M2 in the rear surface Wb as shown in FIG. 13A, the radiation position of the laser light L2 for inside can be appropriately determined as in the above-described exemplary embodiment.

Further, in this case, in order to properly form the internal modification layer M4 inside the first wafer W, it is desirable to set the formation position of the reference modification layer M1 to be slightly outside the formation position of the peripheral modification layer M2 in the radial direction.

Moreover, even in the case where the peripheral portion We of the first wafer W is removed as one body with the rear surface Wb side of the first wafer W, the peripheral modification layers M2 may be obliquely arranged.

In this case, it is desirable to set the formation position of the reference modification layer M1 to be slightly radially outside the peripheral modification layer M2_{low} formed on the radially outermost side among the plurality of peripheral modification layers M2.

Additionally, in the above-described exemplary embodiment, the peripheral modification layer M2 is formed in the internal modifying apparatus 61 after the non-bonding region Ae is formed in the interface modifying apparatus 60. However, the order in which the non-bonding region Ae and the peripheral modification layer M2 are formed is not limited thereto.

In this case, in the internal modifying apparatus 61, by using a macro camera (not shown), alignment of the first wafer W is performed, and the radiation position of the laser light L2 for inside is determined with reference to the outer end of the first wafer W. In other words, the formation position of the peripheral modification layer M2 is determined based on the outer end of the first wafer W.

Further, in the internal modifying apparatus 61, after the peripheral modification layer M2 and the split modification layer M3 are formed, the converging point of the laser light L2 for inside (radiation position of the laser light L2 for inside) is moved to the rear surface Wb of the first wafer W to form the reference modification layer M1, which serves as the determination reference of the radiation position of the laser light L1 for interface (formation position of the non-bonding region Ae).

Additionally, in the interface modifying apparatus 60, by using a micro camera (not shown), alignment of the first wafer W is performed, and the radiation position of the laser light L1 for interface is determined based on the reference modification layer M1. In other words, the formation position of the non-bonding region Ae is determined based on the reference modification layer M1 formed at the rear surface Wb of the first wafer W.

According to the technique of the present disclosure, even in the case where the peripheral modification layer M2 is formed prior to the non-bonding region Ae, the radiation position of the laser light L1 for interface can be determined based on the reference modification layer M1 formed at the rear surface Wb of the first wafer W.

Accordingly, since the reference mark (target) formed at the rear surface Wb of the first wafer W, that is, at the flat surface is detected with the camera, it is possible to use the optical system (micro camera) with the higher numerical aperture NA, as compared to the conventional case where the chamfered outer end (edge portion) is detected with the camera. As a result, more precise adjustment of the radiation position of the laser light L1 for interface (alignment of the laser radiation system 110) can be carried out.

Accordingly, even in the case where the plurality of laser radiation devices (in the present exemplary embodiment, the interface modifying apparatus 60 and the internal modifying apparatus 61) are provided in the wafer processing system 1, the deviation between the formation position of the peripheral modification layer M2 and the formation area of the non-bonding region Ae can be appropriately suppressed. As a consequence, the peripheral portion We of the first wafer W can be appropriately removed.

In addition, in the above-described exemplary embodiment, the separation (edge trimming) of the peripheral portion We of the first wafer W is performed in the separating apparatus 62. However, instead of providing the separating apparatus 62 configured to perform the edge trimming in the wafer processing system 1, the peripheral portion We may be removed in the processing apparatus 80.

To elaborate, when removing the peripheral portion We of the first wafer W independently, the peripheral portion We can be removed from the second wafer S by using grinding resistance generated during the grinding process in the processing apparatus 80. Further, when removing the peripheral portion We of the first wafer W as one body with the rear surface Wb of the first wafer W, the separation of the first wafer W may be performed when the combined wafer T is handed over to the chuck 83 from the wafer transfer device 70 in the processing apparatus 80.

In this case, the processing apparatus 80 functions as a “periphery removing apparatus” according to the technique of the present disclosure.

It should be noted that the above-described exemplary embodiment is illustrative in all aspects and is not anyway limiting. The above-described exemplary embodiment may be omitted, replaced and modified in various ways without departing from the scope and the spirit of claims.

### EXPLANATION OF CODES

1: Wafer processing system
60: Interface modifying apparatus
61: Internal modifying apparatus
62: Separating apparatus
Ae: Non-bonding region
M1: Reference modification layer
M2: Peripheral modification layer
T: Combined wafer
W: First wafer
Wb: Rear surface (of first wafer)
We: Peripheral portion
S: Second wafer

1. A processing method of processing a combined substrate in which a first substrate and a second substrate are bonded to each other, the processing method comprising:
forming a peripheral modification layer along a boundary between a peripheral portion of the first substrate as a removal target and a central portion of the first substrate;
forming a non-bonding region in which bonding strength between the first substrate and the second substrate at the peripheral portion is reduced;
forming a reference modification layer, which serves as a determination reference of a formation position of either the peripheral modification layer or the non-bonding region, at a non-bonding surface of the first substrate not bonded to the second substrate; and
removing the peripheral portion starting from the peripheral modification layer.

2. The processing method of claim 1,
wherein the non-bonding region, the reference modification layer and the peripheral modification layer are formed in this order,
the formation position of the non-bonding region and a formation position of the reference modification layer are determined based on an outer end of the first substrate, and
the reference modification layer is formed to be shifted in a radial direction from a position corresponding to an inner end of the non-bonding region.

3. The processing method of claim 1,
wherein the non-bonding region, the reference modification layer and the peripheral modification layer are formed in this order,
the formation position of the non-bonding region and a formation position of the reference modification layer are determined based on an outer end of the first substrate, and
the reference modification layer is formed to be shifted in a radial direction from a position corresponding to a target formation position of the peripheral modification layer.

4. The processing method of claim 2, further comprising:
detecting the outer end of the first substrate with a first imaging device; and
detecting the reference modification layer formed at the non-bonding surface of the first substrate with a second imaging device,
wherein a numerical aperture of the second imaging device is set to be higher than that of the first imaging device.

5. The processing method of claim 1,
wherein the peripheral modification layer, the reference modification layer and the non-bonding region are formed in this order,
the formation position of the peripheral modification layer and a formation position of the reference modification layer are determined based on an outer end of the first substrate, and
the reference modification layer is formed to be shifted in a radial direction from a position corresponding to the formation position of the peripheral modification layer.

6. The processing method of claim 5, further comprising:
detecting the outer end of the first substrate with a first imaging device; and
detecting the reference modification layer formed at the non-bonding surface of the first substrate with a second imaging device,
wherein a numerical aperture of the first imaging device is set to be higher than that of the second imaging device.

7. The processing method of claim 1, further comprising:
wet-etching the first substrate after being subjected to the removing of the peripheral portion; and
removing, by radiation of laser light, a surface film remaining on a surface of the second substrate exposed as a result of the removing of the peripheral portion.

8. The processing method of claim 7,
wherein the removing of the surface film is performed after the wet-etching of the first substrate.

9. The processing method of claim 1, further comprising:
forming an internal modification layer which serves as a starting point of separating the first substrate,
wherein in the removing of the peripheral portion, the peripheral portion is removed as one body with a portion of a non-bonding side of the first substrate.

10. The processing method of claim 1,
wherein the peripheral modification layer includes multiple peripheral modification layers, and the multiple peripheral modification layers are formed inside the first substrate, and
adjacent peripheral modification layers are formed to be shifted from each other in a thickness direction and a radial direction of the first substrate.

11. A processing system configured to process a combined substrate in which a first substrate and a second substrate are bonded to each other, the processing system comprising:
an internal modifying apparatus configured to form a peripheral modification layer along a boundary between a peripheral portion of the first substrate as a removal target and a central portion of the first substrate;
an interface modifying apparatus configured to form a non-bonding region in which bonding strength between the first substrate and the second substrate at the peripheral portion is reduced;
a reference forming apparatus configured to form a reference modification layer, which serves as a determination reference of a formation position of either the peripheral modification layer or the non-bonding region, at a non-bonding surface of the first substrate not bonded to the second substrate;
a periphery removing apparatus configured to remove the peripheral portion starting from the peripheral modification layer; and
a control device and a program storage including a program.

12. The processing system of claim 11,
wherein the reference forming apparatus and the interface modifying apparatus are provided as one body, and
the program storage and the program are configured, with the control device, to perform:
a control of determining the formation position of the non-bonding region and a formation position of the reference modification layer based on an outer end of the first substrate; and
a control of forming the reference modification layer to be shifted in a radial direction from a position corresponding to an inner end of the non-bonding region.

13. The processing system of claim 11,
wherein the reference forming apparatus and the interface modifying apparatus are provided as one body, and
the program storage and the program are configured, with the control device, to perform:
a control of determining the formation position of the non-bonding region and a formation position of the reference modification layer based on an outer end of the first substrate; and
a control of forming the reference modification layer to be shifted in a radial direction from a position corresponding to a target formation position of the peripheral modification layer.

14. The processing system of claim 12,
wherein the interface modifying apparatus comprises a first imaging device configured to detect the outer end of the first substrate,
the internal modifying apparatus comprises a second imaging device configured to detect the reference modification layer formed at the non-bonding surface of the first substrate, and
a numerical aperture of the second imaging device is set to be higher than that of the first imaging device.

15. The processing system of claim 11,
wherein the reference forming apparatus and the internal modifying apparatus are provided as one body, and
the program storage and the program are configured, with the control device, to perform:
a control of determining the formation position of the peripheral modification layer and a formation position of the reference modification layer based on an outer end of the first substrate; and
a control of forming the reference modification layer to be shifted in a radial direction from a position corresponding to the formation position of the peripheral modification layer.

16. The processing system of claim 15,
wherein the interface modifying apparatus comprises a first imaging device configured to detect the outer end of the first substrate,
the internal modifying apparatus comprises a second imaging device configured to detect the reference modification layer formed at the non-bonding surface of the first substrate, and
a numerical aperture of the first imaging device is set to be higher than that of the second imaging device.

17. The processing system of claim 11, further comprising:
an etching apparatus configured to wet-etch the first substrate obtained after the peripheral portion is removed; and
a cleaning apparatus configured to remove, by radiation of laser light, a surface film remaining on a surface of the second substrate as a result of removing the peripheral portion.

18. The processing system of claim 17,
wherein the program storage and the program are configured, with the control device, to perform a control of removing the surface film in the cleaning apparatus after wet-etching the first substrate in the etching apparatus.

19. The processing system of claim 11,
wherein the program storage and the program are configured, with the control device, to perform a control of forming an internal modification layer, which serves as a starting point of separating the first substrate, in the internal modifying apparatus, and
in removing the peripheral portion in the periphery removing apparatus, the peripheral portion is removed as one body with a portion of a non-bonding side of the first substrate.

20. The processing system of claim 11,
wherein the peripheral modification layer includes multiple peripheral modification layers, and
the program storage and the program are configured, with the control device, to perform, in the internal modifying apparatus,
a control of forming the multiple peripheral modification layers inside the first substrate; and
a control of forming adjacent peripheral modification layers to be shifted from each other in a thickness direction and a radial direction of the first substrate.
